(19) United States
(12) Patent Application Publication
(10) Pub. No.: US 2020/0131637 A1
(43) Pub. Date: Apr. 30, 2020

(54) MODULAR INJECTOR AND DEVICE FOR SPATIAL ATOMIC LAYER DEPOSITION

(71) Applicant: HUAZHONG UNIVERSITY OF SCIENCE AND TECHNOLOGY, Wuhan, Hubei (CN)

(72) Inventors: Rong CHEN, Wuhan, Hubei (CN); Xiaolei WANG, Wuhan, Hubei (CN); Bin SHAN, Wuhan, Hubei (CN); Yun LI, Wuhan, Hubei (CN); Jilong LIN, Wuhan, Hubei (CN); Yuchun MA, Wuhan, Hubei (CN); Wei DAN, Wuhan, Hubei (CN)

(73) Assignee: Huazhong University of Science and Technology, Wuhan, Hubei (CN)

(21) Appl. No.: 16/493,208

(22) PCT Filed: Jan. 24, 2018
(86) PCT No.: PCT/CN2018/073996

§ 371 Date: Sep. 11, 2019

(30) Foreign Application Priority Data
May 13, 2017 (CN) 201710336412.6

(51) Int. Cl. C23C 16/455

(52) U.S. Cl. CPC C23C 16/45551; C23C 16/45563

(57) ABSTRACT

A modular injector includes a precursor channel assembly and a seal assembly; the precursor channel assembly includes a plate-shaped base, a precursor channel and a gas pipeline; the precursor channel is disposed on a front surface of the plate-shaped base and extends from top to bottom, and a top end of the precursor channel is communicated with the gas pipeline; the seal assembly is disposed on the front surface of the plate-shaped base. The modular injector includes a plurality of components to form an integral module, and shunts and buffers the introduced gas through the precursor channel to achieve uniform deposition. A device includes multiple modular injectors arranged at an interval, into which the oxidant precursor source and the organo-metallic source are respectively introduced, so that multiple stages of film are deposited on the substrate after the substrate moves for a round trip.

### BACKGROUND

### Technical Field

The disclosure belongs to the field of atomic layer deposition, and more particularly relates to a modular injector and device for spatial atomic layer deposition.

### Description of the Related Art

Flexible electronics have broad application prospects in the fields of information, energy, medical treatment, flexible display and so on due to its unique flexibility, ductility and low-cost manufacturing process. The manufacturing process of the flexible electronics includes: material preparation, thin film deposition, patterning, packaging and functional integration, in which the performance of the thin film layer directly determines the electrical, mechanical and sealing properties of the flexible electronic device. Compared with traditional thin film preparation techniques such as chemical vapor deposition (CVD) and physical vapor deposition (PVD), the atomic layer deposition (ALD) has the obvious advantages of high step coverage, large area deposition and precise control at nanometer scale. However, the conventional temporal atomic layer deposition film has the disadvantage of low preparation efficiency, and thus cannot meet the requirements for large-scale and low-cost production. Spatial atomic layer deposition utilizes the inert gas to separate different precursors, and achieves the continuous growth of the film by the reciprocating motion of the substrate underneath the injectors, thereby greatly improving the film preparation efficiency. In addition, the growth of the film exhibits a strong linearity, and the film thickness can be controlled by controlling the number of cycles. Therefore, this technology has broad prospects in the fields of solar cells, flexible electronics, photovoltaics and so on.

At present, the spatial atomic layer deposition technology is faced with a key issue of how to ensure the uniformity of the deposited film during the high-speed movement of the substrate.

### SUMMARY

In view of the above-described defects or improvement requirements in the art, the disclosure provides a modular injector and device for spatial atomic layer deposition, which aims to shunt and buffer the introduced gas through the precursor channel so as to solve the problems that the film grows unevenly during high-speed movement of the substrate and the precursors are prone to cross-contamination in the spatial atomic layer deposition system, thereby achieving efficient and fast large-area uniform film deposition.

In order to achieve the above objective, the disclosure provides a modular injector for spatial atomic layer deposition, comprising: a precursor channel assembly and a seal assembly; the precursor channel assembly includes a plate-shaped base, a precursor channel and a gas pipeline; the precursor channel is disposed on a front surface of the plate-shaped base and extends from top to bottom, and a top end of the precursor channel is communicated with the gas pipeline; the seal assembly is disposed on the front surface of the plate-shaped base to seal the precursor channel so as to prevent the leakage of the precursor.

Further, the precursor channel includes multiple stages of shunt channels and one stage of precursor diffusion region; the multiple stages of shunt channels are disposed from top to bottom, and the number of the shunt channels is increased stage by stage to uniformly shunt a precursor supplied from the gas pipeline into multiple parts; the precursor diffusion region is disposed under the shunt channels in the lowest stage to communicate the shunt channels in the lowest stage with each other, so that the precursor fully diffuses before reaching the reaction substrate.

Further, there are 2ⁿ shunt channels in a n-th stage, each of the shunt channels is shunted into two in the next stage, and the shunt channels in the last stage are communicated with each other through the precursor diffusion region.

Further, the precursor channel includes four stages of shunt channels and one stage of precursor diffusion region;

first to fourth stage shunt channels are disposed from top to bottom, wherein gas inlets of the first-stage shunt channels divides the precursor into two parts through symmetrical ramps; the fourth-stage shunt channels each has an inlet and an outlet with cone-shaped cross-sections to generate a change in fluid pressure drop, which is conducive to the diffusion of the precursor; the precursor diffusion region is disposed under the fourth-stage shunt channels to communicate the fourth-stage shunt channels with each other, so that the precursor fully diffuses before reaching the reaction substrate.

Further, the seal assembly includes a seal plate, a seal ring groove, a seal assembly heating region and a seal ring;

the seal plate is mounted on the plate-shaped base in a manner that a front surface of the seal plate faces the front surface of the plate-shaped base; the seal ring groove disposed on the front surface of the seal plate, and the seal ring is mounted in the seal ring groove to seal the seal plate and the plate-shaped base so as to prevent the leakage of the precursor; the seal assembly heating region is disposed on a back surface of the seal plate corresponding to the precursor channel;

the precursor channel assembly includes a precursor channel heating region disposed on a back surface of the plate-shaped base corresponding to the precursor channel; the seal assembly heating region and the precursor channel heating region are both used for heating the precursor channel.

In order to achieve the above objective, the disclosure further provides a device for spatial atomic layer deposition, comprising the modular injector according to any one of the above paragraphs.

In order to achieve the above objective, the disclosure further provides a device for spatial atomic layer deposition for precursor deposition on a reaction substrate, characterized by comprising a case, distance measurement sensors, an exhaust assembly and a plurality of modular injectors according to any one of the above paragraphs; a cavity penetrating upper and lower surfaces is disposed in a middle portion of the case; the modular injectors are arranged along an advancing direction of the reaction substrate, and mounted in the cavity with the precursor diffusion regions facing down; the distance measurement sensors are mounted on the case to measure a distance between the bottom of the injector and the reaction substrate; and the exhaust assembly is sealingly mounted on an upper portion of the case, and has a gas cavity that opens downwards and is placed over the modular injectors to fill in the inert gas during the deposition reaction so as to provide an inert environment.

Further, the cavity has two side walls on two sides of the movement direction of the reaction substrate, and the two side walls are each provided with a distance adjusting groove; the distance adjusting grooves are disposed along the movement direction of the reaction substrate, and penetrate the side walls; and each of the modular injectors is provided an adjustment rod on each side, and the adjustment rods are disposed in the corresponding distance adjustment grooves on both sides.

Further, the exhaust assembly includes a case cover, a first inert gas interface, an oxidant precursor interface, an organo-metallic precursor interface, a negative pressure interface and a second inert gas interface;

the gas cavity is disposed in the case cover; the first inert gas interface, the oxidant precursor interface, the organo-metallic precursor interface, the second inert gas interface and the negative pressure interface are all disposed on the case cover and communicated with the gas cavity;

the first inert gas interface, the oxidant precursor interface and the organo-metallic precursor interface are respectively connected to the corresponding modular injectors to supply the inert gas, oxidant precursor and organo-metallic precursor to the respective modular injectors;

the second inert gas interface is configured to introduce an inert gas into the gas cavity to form an inert environment; and

the negative pressure interface is configured to extract residual gases and excess by-products from the reaction.

Further, the modular injectors include seven modular injectors, into which the inert gas, the oxidant precursor, the inert gas, the organo-metallic precursor, the inert gas, the oxidant precursor and the inert gas are respectively introduced in the movement direction of the reaction substrate.

In general, by comparing the above technical solution of the present inventive concept with the prior art, the disclosure has the following beneficial effects:

(1) The modular injector of the disclosure is composed by a plurality of components to form an integral module, which shunts and buffers the introduced gas through the precursor channel to achieve uniform deposition, and any number of modular injectors can be combined according to actual needs.

(2) The precursor channel shunts the introduced precursor stage by stage through the multiple stages of shunt channels, and multiple identical channel structures can be duplicated according to the size of the substrate to be deposited to adapt to the requirement of the substrate size, thereby achieving the thin film deposition of the large-area substrate.

(3) The precursor channel includes four stages of shunt channels, so that the gas is evenly divided into sixteen parts; the last-stage shunt channels in the four stages of shunt channels adopts a cone-shaped cross-section, so that the precursor changes in pressure when flowing through the cross-section, which is more conducive to uniform diffusion of the precursor and achieves uniform deposition of the film.

(4) Since the film deposition is carried out at atmospheric pressure, the injector is easy to be clogged. In the present disclosure, the modular injector is mechanically assembled and connected by the channel structure and the seal structure, which are convenient for disassembly and cleaning. In addition, any injector can be replaced and cleaned separately due to the injector modularity, without affecting the normal use of the device.

(5) The precursor unit includes seven modular injectors arranged at an interval, and two oxidant precursor sources and one organo-metallic source are included, so that two layers of film are deposited on the substrate after the substrate moves for a round trip under the precursor unit, thereby greatly improving the film deposition efficiency.

(6) Through the cooperation of the distance adjusting groove and the distance adjusting rods on the case, the interval between the respective injectors can be freely adjusted according to the deposition process requirement to prevent the cross-contamination of the precursors, thereby achieving the uniform deposition of the film.

(7) Through distance measurement sensors, a distance between the reaction substrate when entering the precursor unit and the reaction substrate when exiting the precursor unit can be measured in real time, so that the distance between the two can be controlled within the range allowed by the process.

(8) The exhaust assembly of the present disclosure can form an inert protective atmosphere and remove residual gases and reaction by-products during film deposition in real time, thereby ensuring a good film deposition environment.

### BRIEF DESCRIPTION OF THE DRAWINGS

FIG. 1 is an overall structural diagram of a modular injector;

FIG. 2(a) is a schematic perspective structural diagram of a precursor channel assembly of the modular injector;

FIG. 2(b) is a bottom view of FIG. 2(a);

FIG. 2(c) is a schematic diagram showing a multistage structure of the precursor channel in FIG. 2(a);

FIG. 3(a) is a schematic perspective structural diagram of a seal assembly of the modular injector;

FIG. 3(b) is a bottom view of FIG. 3(a);

FIG. 4 is a schematic overall diagram of a reaction device;

FIG. 5 is a schematic structural diagram of a precursor unit;

FIG. 6(a) is a schematic perspective structural diagram of a case;

FIG. 6(b) is a front view of FIG. 6(a);

FIG. 7(a) is a schematic perspective structural diagram of an exhaust assembly;

FIG. 7(b) is a plan view of FIG. 7(a).

### DETAILED DESCRIPTION OF THE EMBODIMENTS

For clear understanding of the objectives, features and advantages of the disclosure, detailed description of the disclosure will be given below in conjunction with accompanying drawings and specific embodiments. It should be noted that the embodiments described herein are only meant to explain the disclosure, and not to limit the scope of the disclosure. Furthermore, the technical features related to the embodiments of the disclosure described below can be mutually combined if they are not found to be mutually exclusive.

The basic idea and principle of the disclosure are as follows:

In accordance with one aspect of the disclosure, a modular injector is provided for achieving uniform supply of a precursor to fabricate an atomic layer deposition film, including a precursor channel assembly, a seal assembly, and a heating assembly, in which the precursor channel assembly is divided into four regions: a precursor inlet region, a precursor shunt region, a precursor diffusion region and a heating region; the precursor inlet region is a cylindrical cavity and is connected to an external gas pipeline by welding; the precursor shunt region shunts a precursor into multiple parts by stage-by-stage shunting to achieve uniform dispersion of the precursor, and the inlets and outlets of the last-stage shunt channels adopt a cone-shaped structure, which is conducive to the diffusion of the precursor; the precursor diffusion region is a wedge-shaped cavity having an isosceles trapezoidal cross-section, and is used for uniformly diffusing the precursor flowing out of the last-stage shunt channels onto the reaction substrate; the heating region is disposed on the back side of the precursor channel region to uniformly heat the precursor; the seal assembly is provided with a standard groove for mounting the seal ring to seal the precursor channel assembly; the heating assembly includes heated sheets fixed to the precursor channel assembly and the seal assembly to uniformly heat the precursor flowing through the precursor channel.

In accordance with another aspect of the disclosure, there is provided a reaction device for spatial atomic layer deposition for efficiently and rapidly depositing a uniform film, including a precursor unit, a distance measurement system an exhaust assembly; the precursor unit includes seven modular injectors as set forth above to form a spatial atomic layer deposition precursor unit; the case is configured to fix the injectors to form a reaction unit, and a distance between the respective modular injectors in the precursor unit is adjusted; the distance measurement system is disposed on the case to measure a distance between the precursor unit and the reaction substrate in real time; the exhaust assembly is disposed above the case to provide an inert gas environment and remove residual gases and reaction by-products.

Hereinafter, preferred embodiments of the disclosure will be described in detail with reference to the accompanying drawings.

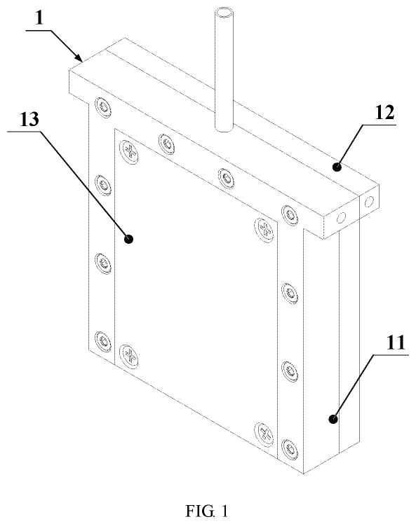

The disclosure provides a modular injector and device for spatial atomic layer deposition. As shown in FIG. 1, the modular injector 1 comprises a precursor channel assembly 11, a seal assembly 12 and a heating assembly 13. The seal assembly 12 and the precursor channel assembly 11 are sealed by a seal ring; the heating assembly 13 uniformly heats the precursor flowing through the internal precursor channel by a seal assembly heating region and a precursor channel heating region which are respectively fixed to the back surface of the seal assembly 12 and the back surface of the precursor channel assembly 11 by countersunk screws.

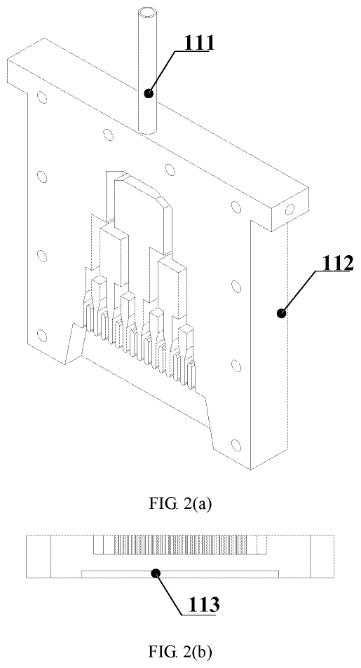

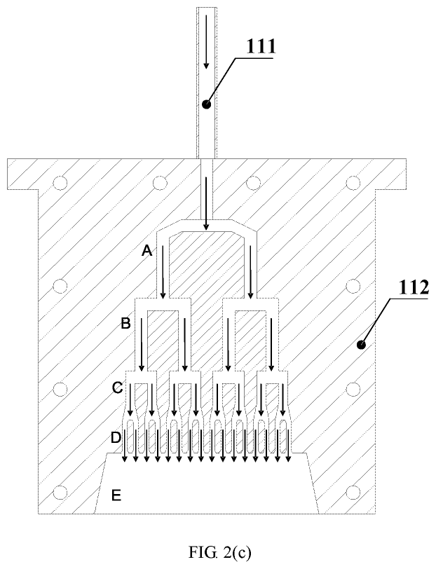

FIGS. 2(a)-2(c) are schematic structural diagrams of the precursor channel assembly 11, which mainly includes a gas pipeline 111, a precursor channel 112 and a precursor channel heating region 113. FIG. 2(c) is a schematic diagram showing a multistage structure of the precursor channel 112 and the flow direction of the precursor, comprising four stages of shunt channels A, B, C and D, and a stage of precursor diffusion region E. The first-stage shunt channels A uniformly separate the precursor into two parts by symmetrical ramps, the ramps are designed for better change in gas velocity direction; the second-stage shunt channels B and the third-stage shunt channels C each have a minimum height that ensures the consistency in direction and velocity of the precursor at the exit of each stage, so that the uniform gas distribution is achieved while the size of the entire injector is minimized; the fourth-stage shunt channels D have gas inlets and gas outlets with cone-shaped cross-sections to produce a change in gas pressure drop, which is more conducive to the diffusion of the gas; the precursor diffusion region E is ensured to have a certain height such that the precursor fully diffuses in the vertical direction before reaching the reaction substrate, ensuring that the precursor is uniformly distributed when reaching the reaction substrate. FIGS. 3(a) and 3(b) are schematic structural diagrams of the seal assembly 12, which mainly includes a sealing layer 121, a seal ring groove 122 and a seal assembly heating region 123, in which the seal ring groove 122 is standardly designed and manufactured according to the type of the selected seal ring.

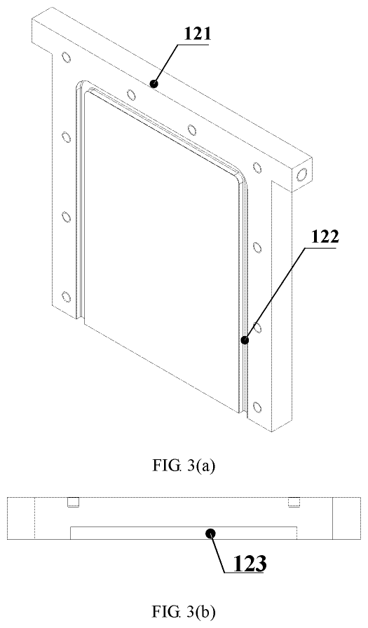

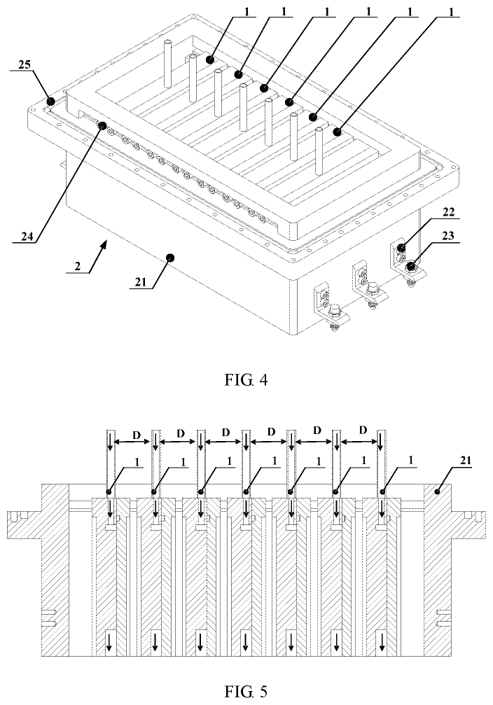

FIG. 4 shows an overall schematic diagram of a reaction device, which includes modular injectors 1 and a support assembly 2. The support assembly 2 includes a case 21, sensor supports 22, distance measurement sensors 23, adjustment levers 24, and an exhaust assembly seal ring 25. Seven modular injectors 1 constitute a precursor unit, into which an inert gas, an oxidant precursor, an inert gas, an organo-metallic precursor, an inert gas, an oxidant precursor and an inert gas are respectively introduced in sequence, so that two layers of film are deposited on the substrate after the substrate moves for a round trip under the precursor unit. Three distance measurement sensors 23 are arranged on each of the left and right sides of the case to form a distance measurement system, which measures a distance between the reaction substrates when entering and exiting the precursor unit in real time, so that the distance between the two can be controlled. FIG. 5 shows a schematic structural diagram of the precursor unit, in which a distance D between the respective modular injectors 1 has an important influence on the film deposition. In the present embodiment, the adjustment lever 24 is a bolt, the modular injector 1 is moved by moving the adjustment lever 24 to adjust the distance D so as to meet different deposition process requirements.

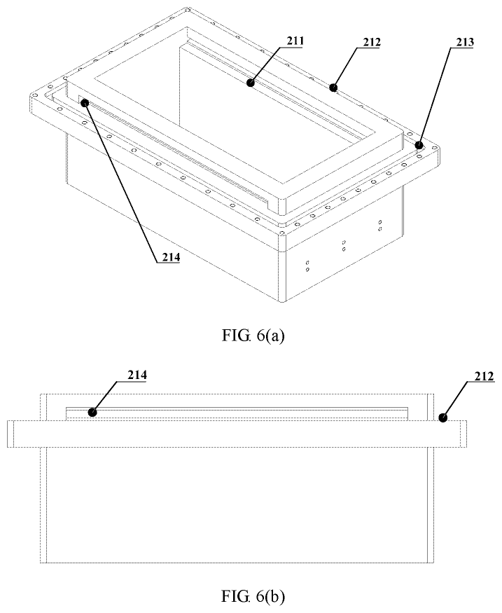

FIGS. 6(a) and 6(b) are schematic diagrams showing the overall structure of the case 21, which includes an injector support seat 211, an exhaust support seat 212, a seal ring groove 213 and a distance adjustment groove 214. The adjustment levers 24 are moved in the distance adjustment groove 214 to adjust the distance D between the respective modular injectors 1.

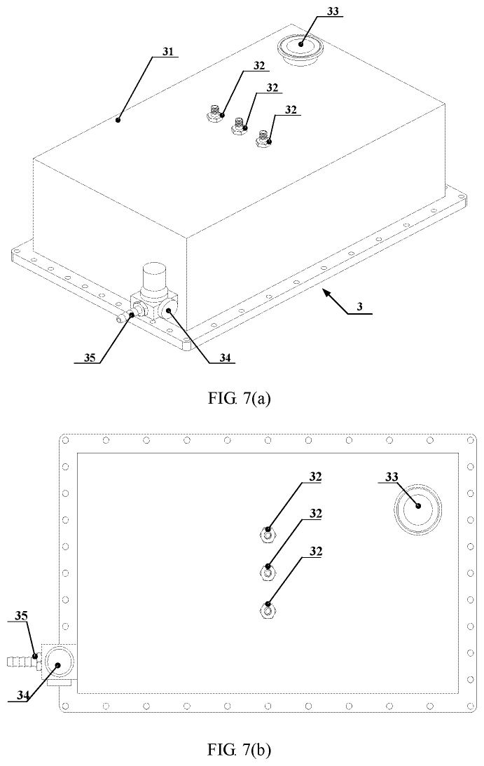

FIGS. 7(a) and 7(b) are schematic diagrams showing the overall structure of an exhaust assembly 3, which includes a case cover 31, gas pipeline quick joints 32, a flange joint 33, a pressure reducing valve 34 and a pagoda joint 35. The case cover 31 is made of glass for easy observation of internal conditions. The glass case cover 31 is fixed to the exhaust support seat of the case by a seal ring 31 and bolts. As shown in the figures, the glass case cover 31 is provided with three gas pipeline quick joints 32 (i.e., a first inert gas interface, an oxidant precursor interface and an organo-metallic precursor interface, respectively), into which an inert gas, an oxidant precursor and an organo-metallic precursor are introduced. The three gas pipeline quick joints are connected to the respective modular injectors 1 by adapters and soft gas pipelines to supply gas to the precursor unit. The pagoda joint 35 (i.e., a second inert gas interface) is connected to an inert gas source, and introduces the inert gas into the glass case cover 31 through the pressure reducing valve 34 to provide an inert environment for the precursor unit. Meanwhile, a negative pressure is provided at the flange joint 33 (i.e., a negative pressure interface) to pump out residual gases and excess by-products generated by the reaction so as to ensure a good deposition environment.

It should be readily understood to those skilled in the art that the above description is only preferred embodiments of the disclosure, and does not limit the scope of the disclosure. Any change, equivalent substitution and modification made without departing from the spirit and scope of the disclosure should be included within the scope of the protection of the disclosure.

1. A modular injector for spatial atomic layer deposition for precursor deposition on a reaction substrate, comprising: a precursor channel assembly and a seal assembly;
the precursor channel assembly includes a plate-shaped base, a precursor channel and a gas pipeline; the precursor channel is disposed on a front surface of the plate-shaped base and extends from top to bottom, and a top end of the precursor channel is communicated with the gas pipeline;
the seal assembly is disposed on the front surface of the plate-shaped base to seal the precursor channel so as to prevent the leakage of a precursor.

2. The modular injector for spatial atomic layer deposition according to claim 1, wherein the precursor channel includes multiple stages of shunt channels and one stage of precursor diffusion region; the multiple stages of shunt channels are disposed from top to bottom, and the number of the shunt channels is increased stage by stage to uniformly shunt a precursor supplied from the gas pipeline into multiple parts; the precursor diffusion region is disposed under the shunt channels in the lowest stage to communicate the shunt channels in the lowest stage with each other, so that the precursor fully diffuses before reaching the reaction substrate.

3. The modular injector for spatial atomic layer deposition according to claim 2, wherein there are 2ⁿ shunt channels in a n-th stage, each of the shunt channels is shunted into two in the next stage, and the shunt channels in the last stage are communicated with each other through the precursor diffusion region.

4. The modular injector for spatial atomic layer deposition according to claim 3, wherein the precursor channel includes four stages of shunt channels and one stage of precursor diffusion region;
first to fourth stage shunt channels are disposed from top to bottom, wherein gas inlets of the first-stage shunt channels divides the precursor into two parts through symmetrical ramps; the second-stage shunt channels and the third-stage shunt channels have a minimum height which enables the consistency in direction and velocity of the precursor when flowing out of respective outlets of the third-stage shunt channels; the fourth-stage shunt channels each has an inlet and an outlet with cone-shaped cross-sections to generate a change in fluid pressure drop, which is conducive to the diffusion of the precursor; the precursor diffusion region is disposed under the fourth-stage shunt channels to communicate respective outlets of the fourth-stage shunt channels with each other, so that the precursor fully diffuses before reaching the reaction substrate.

5. The modular injector for spatial atomic layer deposition according to claim 1, wherein the seal assembly includes a seal plate, a seal ring groove, a seal assembly heating region and a seal ring;
the seal plate is mounted on the plate-shaped base in a manner that a front surface of the seal plate faces the front surface of the plate-shaped base; the seal ring groove disposed on the front surface of the seal plate, and the seal ring is mounted in the seal ring groove to seal the seal plate and the plate-shaped base so as to prevent the leakage of the precursor; the seal assembly heating region is disposed on a back surface of the seal plate corresponding to the precursor channel;
the precursor channel assembly includes a precursor channel heating region disposed on a back surface of the plate-shaped base corresponding to the precursor channel; the seal assembly heating region and the precursor channel heating region are both used for heating the precursor channel.

6. A device for spatial atomic layer deposition for precursor deposition on a reaction substrate, comprising the modular injector according to claim 1.

7. A device for spatial atomic layer deposition for precursor deposition on a reaction substrate, comprising a case, distance measurement sensors, an exhaust assembly and a plurality of modular injectors according to claim 1;
a cavity penetrating upper and lower surfaces is disposed in a middle portion of the case;
the modular injectors are arranged along an movement direction of the reaction substrate, and mounted in the cavity with the precursor diffusion regions facing down;
the distance measurement sensors are mounted on the case to measure a distance between the case and the reaction substrate; and
the exhaust assembly is sealingly mounted on an upper portion of the case, and has a gas cavity that opens downwards and is placed over the modular injectors to fill in an inert gas during the deposition reaction so as to provide an inert environment.

8. The device for spatial atomic layer deposition according to claim 7, wherein the cavity has two side walls on two sides of the movement direction of the reaction substrate, and the two side walls are each provided with a distance adjusting groove; the distance adjusting grooves are disposed along the movement direction of the reaction substrate, and penetrate the side walls;
each of the modular injectors is provided an adjustment rod on each side, and the adjustment rods are disposed in the corresponding distance adjustment grooves on both sides.

9. The device for spatial atomic layer deposition according to claim 7, wherein the exhaust assembly includes a case cover, a first inert gas interface, an oxidant precursor interface, an organo-metallic precursor interface, a negative pressure interface and a second inert gas interface;
the gas cavity is disposed in the case cover; the first inert gas interface, the oxidant precursor interface, the organo-metallic precursor interface, the second inert gas interface and the negative pressure interface are all disposed on the case cover and communicated with the gas cavity;
the first inert gas interface, the oxidant precursor interface and the organo-metallic precursor interface are respectively connected to the corresponding modular injectors to supply an inert gas, an oxidant precursor and an organo-metallic precursor to the respective modular injectors;
the second inert gas interface is configured to introduce an inert gas into the gas cavity to form an inert environment; and
the negative pressure interface is configured to extract residual gases and excess by-products from the reaction.

10. The device for spatial atomic layer deposition according to claim 7, wherein the modular injectors include seven modular injectors, into which the inert gas, the oxidant precursor, the inert gas, the organo-metallic precursor, the inert gas, the oxidant precursor and the inert gas are respectively introduced in the advancing direction of the reaction substrate.
